(19) United States
(12) Patent Application Publication
(10) Pub. No.: US 2025/0233330 A1
(43) Pub. Date: Jul. 17, 2025

(54) PRINTED CIRCUIT BOARD ASSEMBLY WITH SNAP INTERFACE FOR ELECTRICAL CONNECTION

(71) Applicant: Webasto Charging Systems, Inc., Monrovia, CA (US)

(72) Inventors: Marcel Marquardt, Arcadia, CA (US); Peter Gabrielsson, Monrovia, CA (US); Herman Joseph Steinbuchel, IV, Pasadena, CA (US); Kent Hayes, Upland, CA (US); George De La Rosa, Glendale, CA (US)

(21) Appl. No.: 18/412,290

(22) Filed: Jan. 12, 2024

(51) Int. Cl. H01R 12/52; H01R 12/71; H01R 13/627; H05K 1/14

(52) U.S. Cl. CPC H01R 12/523; H01R 12/716; H01R 13/6272; H05K 1/141

(57) ABSTRACT

A circuit board assembly comprises a body portion configured to maintain an electrical circuit thereon, and at least one engagement mechanism at a periphery of the body portion, where the engagement mechanism is configured to mechanically engage an external component and provide electrical connection between the electrical circuit and the external component.

### TECHNICAL FIELD

Embodiments relate generally to a circuit board, and more particularly to a circuit board for electrical connection.

### BACKGROUND

A printed circuit board assembly (PCBA) is a completed board that contains a printed circuit board and required electrical components installed thereon for desired application. This PCBA can be electrically connected to another PCBA and/or electrical/mechanical components for various purposes. To establish an electrical connection between a PCBA and another PCBA or other electrical/mechanical components, a separate electrically conductive component such as an electrical connector is required. This separate conductive component is positioned on, and conductively connected to, a PCBA via an additional connection process, such as soldering.

### SUMMARY

An embodiment of a board disclosed herein comprises a body portion configured to maintain an electrical circuit thereon, and at least one engagement mechanism at a periphery of the body portion, wherein the engagement mechanism is configured to mechanically engage an external component and provide electrical connection between the electrical circuit and the external component. In one embodiment, the engagement mechanism comprises a snap-fit interface configured to mechanically engage an external component and provide electrical connection between the electrical circuit and the external component.

A board assembly embodiment may include: a body portion configured to maintain an electrical circuit thereon; and at least one engagement mechanism at a periphery of the body portion, where the engagement mechanism may be configured to mechanically engage an external component, and provide electrical connection between the electrical circuit and the external component.

In additional board assembly embodiments, the engagement mechanism comprises a snap structure. In additional board assembly embodiments, each snap structure comprises: a set of arm portions extending from a side of the body portion; and a set of snap portions, the snap portions formed on ends of the arm portions. In additional board assembly embodiments, each snap structure further comprises: a set of electrically conductive edge-plates, the edge-plates formed on edge surfaces of the snap portions.

Additional board assembly embodiments may include: an electrically conductive trace extending across top surfaces of the body portion, the set of arm portions, and the set of snap portions, where the trace may be connected between the electrical circuit to at least one of the set of edge-plates. In additional board assembly embodiments, the body portion, the set of arm portions, and the set of snap portions from an integrated body.

In additional board assembly embodiments, the integrated body has a laminated sandwich structure including at least one insulating layer, and the body portion; and the set of arm portions, and the set of snap portions share the at least one insulating layer. In additional board assembly embodiments, each of the arm portions includes a first arm surface, a second arm surface opposite to the first arm surface, an inner arm side facing the other arm portion of the set of arm portions and an outer arm side opposite to the inner arm side.

In additional board assembly embodiments, the body portion has a first body surface, a second body surface opposite to the first body surface, and a body side between an edge of the first body surface and an edge of the second body surface; the outer arm sides protrude from the body side; and the inner arm sides protrude from the body side. In additional board assembly embodiments, each of the edge surfaces of the snap portions includes: a proximal end point, a distal end point positioned away from the proximal end point, and a medial end point positioned between the proximal end point and the far end point; and a distance between the medial end points may be wider than a distance between the proximal end points and a distance between the distal end points.

In additional board assembly embodiments, a distance between the medial end points of the plates corresponding to the medial end points of the snap portions may be wider than a distance between end proximal points of the plates corresponding to the proximal end points of the snap portions and a distance between distal end points of the edge-plates corresponding to the distal end points of the snap portions. In additional board assembly embodiments, each of the edge surfaces of the snap portions and each of the edge-plates on each of the end surfaces of the snap portions, comprises at least one of: concave, circle, ellipse and oval shape; each of the arm portions includes a wave shape having at least one of: a sine wave and a square wave; and the trace formed on the arm portions has a wave shape according to the wave shape of the arm portions. In additional board assembly embodiments, outer arm sides of the arm portions may be formed with an electrically non-conductive material thereon.

A printed circuit board assembly embodiment may include: a printed circuit board having a body portion to maintain an electrical circuit thereon; at least one snap-fit mechanism, each snap-fit mechanism comprising: at least one arm portion formed on a side of the body portion; a set of snap portions formed on at least one end of the at least one arm portion; at least one edge-plate formed on edge surfaces of the snap portions; and an electrically conductive trace connected between the electrical circuit and the at least one edge-plate.

In additional printed circuit board assembly embodiments, the at least one arm portion comprises a single arm portion, and the snap portions branch off from an end of the single arm portion, and where the at least one edge-plate comprises a single edge-plate that continuously extends from at least one of the edge surfaces of the snap portions to the other of the edge surfaces of the snap portions. In additional printed circuit board assembly embodiments, the at least one arm portion comprises a set of arm portions, and the snap portions may be formed on ends of the arm portions, and the at least one edge-plate comprises a single plate continuously formed on the edge surfaces of: the snap portions, inner arm sides of the arm portions, and the body side of the body portion disposed between the arm portions.

Additional printed circuit board assembly embodiments may include a plurality of spaced snap structures. Additional printed circuit board assembly embodiments may include a plurality of snap structures having at least two different shapes.

A method of connecting electrical components embodiment may include: providing a board assembly comprising a body portion configured to maintain an electrical circuit thereon, and at least one snap-fit engagement mechanism at a periphery of the body portion, where the engagement mechanism may be configured to mechanically engage an external component, and provide electrical connection between the electrical circuit and the external component; and connecting the board assembly to an electrical component by pressing the snap-fit engagement mechanism against the electrical component to engage, and electrically connect to, the electrical component via the snap-fit engagement mechanism.

In additional method embodiments, the snap-fit engagement mechanism may be electrically conductive.

### BRIEF DESCRIPTION OF THE DRAWINGS

The components in the figures are not necessarily to scale, emphasis instead being placed upon illustrating the principals of the invention. Like reference numerals designate corresponding parts throughout the different views. Embodiments are illustrated by way of example and not limitation in the figures of the accompanying drawings, in which:

FIG. 1 illustrates a top view of a printed circuit board assembly (PCBA), according to an embodiment of the disclosure herein;

FIG. 2 illustrates a top perspective view of a board without plates formed on edge surfaces of a set of snap portions, according to an embodiment of the disclosure;

FIG. 3A depicts a magnified view of a portion M of the board in FIG. 2 illustrating a set of arm portions and a set of snap portions, according to an embodiment of the disclosure;

FIG. 3B depicts a magnified view of a portion M of FIG. 2 wherein an edge-plate is formed on edge surfaces of a set of snap portions, according to an embodiment of the disclosure;

FIG. 4 depicts a top view of a disassembled portion M of the board in FIG. 2, according to an embodiment of the disclosure;

FIG. 5A depicts an outer side view of a board in FIG. 4, according to an embodiment of the disclosure;

FIG. 5B depicts an inner side view of a board, which is viewed from a line A-A in FIG. 4, according to an embodiment of the disclosure;

FIG. 6A depicts a top perspective view of a board without plates formed on edge surfaces of a set of snap portions, the board on which an electrical circuit or a conductive component may be disposed, according to an embodiment of the disclosure;

FIG. 6B depicts a bottom perspective view of a board without plates formed on edge surfaces of a set of snap portions, the board on which an electrical circuit or a conductive component may be disposed, according to an embodiment of the disclosure;

FIG. 7 depicts a bottom perspective view of a board where an external electrical component may be snapped on a set of snap portions with plates and form a direct contact with the board, according to an embodiment of the disclosure;

FIG. 8 depicts a top view of a board including a set of arm portions with a square wave shape, according to an embodiment of the disclosure;

FIG. 9 depicts a top view of a board comprising a single arm portion, according to an embodiment of the disclosure;

FIG. 10 depicts a top view of a board comprising a single plate for a set of arm portions and a set of snap portions, according to an embodiment of the disclosure; and

FIG. 11 depicts a board with a plurality of snap structures having different shapes, according to an embodiment of the disclosure;

FIG. 12 depicts a top view of a board without plates formed on edge surfaces of a set of snap portions, according to an embodiment of the disclosure;

FIG. 13A depicts a top perspective view of a board without plates formed on edge surfaces of a set of snap portions, according to an embodiment of the disclosure;

FIG. 13B depicts a bottom perspective view of a board without plates formed on edge surfaces of a set of snap portions, according to an embodiment of the disclosure.

### DETAILED DESCRIPTION

The present disclosure provides an electrical board configured to make a direct electromechanical connection to another circuit board or external component. In one embodiment the board comprises a body portion configured to maintain an electrical circuit thereon, and at least one engagement mechanism at a periphery of the body portion, wherein the engagement mechanism is configured to mechanically engage an external component, and provide electrical connection between the electrical circuit and the external component. In one embodiment, the engagement mechanism comprises a snap structure.

In one embodiment, the disclosed board comprises a snap-fit (snap-hook) interface mechanism including a snap structure configured to allow the circuit board to be mechanically engaged (e.g., snapped) directly onto other circuit boards or electrical components, thereby eliminating the need for a separate electrical connector and additional connection processes. Said snap-fit mechanism includes interlocking elements that allow an assembly method for attaching flexible parts by pressing the parts together.

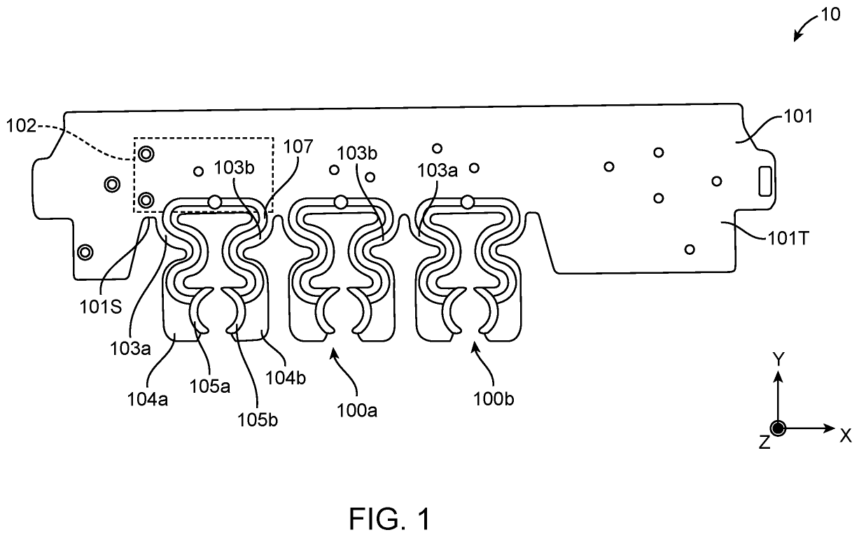

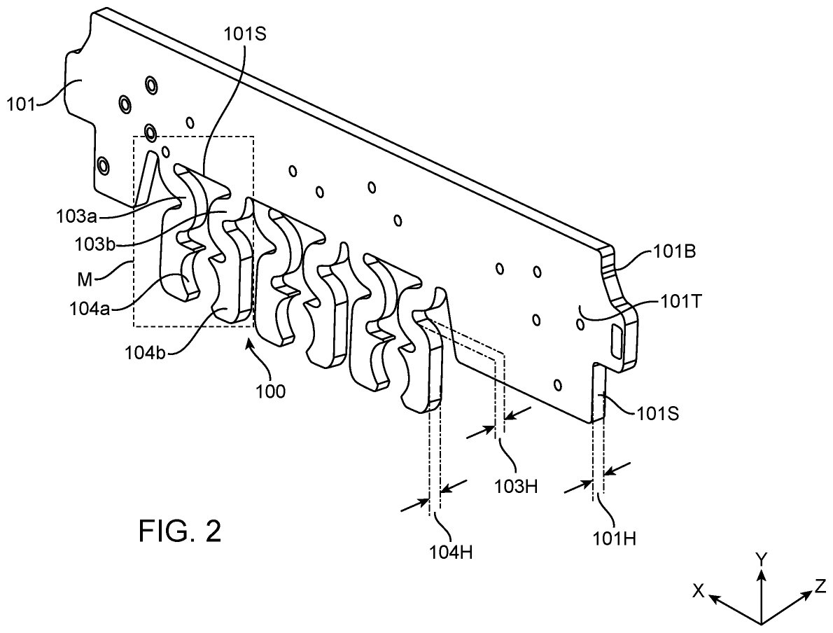

FIG. 1 shows a top view of an electrical circuit board, according to embodiments disclosed herein. FIG. 2 shows a top perspective view of the circuit board of FIG. 1 board, illustrating a body portion, a set of arm portions, and a set of snap portions without plates on edge surfaces of a set of snap portions.

FIG. 1 shows a top view of a board 10, according to embodiments disclosed herein, and FIG. 2 shows a perspective view of the board 10. In one embodiment disclosed herein, the board 10 may comprise: a body portion 101 on which an electrical circuit or a conductive component 102 may be disposed, and at least one snap-fit engagement mechanism such as snap structure 100. One embodiment, the snap structure 100 comprises a set of arm portions 103a, 103b outwardly extending from a body side 101S of the body portion 101; a set of snap portions 104a, 104b formed on ends of the set of arm portions 103a, 103b, respectively; a set of plates 105a, 105b formed on edge surfaces of the snap portions 104a, 104b, respectively; and an electrically conductive trace 107 extended across the body portion 101, the set of arm portions 103a, 103b and the snap portions 104a, 104b, and connecting between the electrical circuit 102 and the set of plates 105a, 105b.

In the embodiment shown in FIGS. 1 and 2, the set of arm portions 103a, 103b, the set of snap portions 104a, 104b formed on the ends of the arm portions 103a, 103b, the set of plates 105a, 105b formed on the end surfaces of the snap portions 104a, 104b, and the trace 107 may form one snap structure 100. The board 10 may include a plurality of snap structures 100. The plurality of the snap structures 100 may comprise a first snap structure 100a and a second snap structure 100b that in one implementation are positioned on at least one periphery of the body portion 101. The first snap structure 100a and the second snap structure 100b may be separated from each other and not share any arm portions. For example, the first snap structure 100a may have its own two arm portions 103a, 103b, and the second snap structure 100b also may have its own two arm portions 103a, 103b different from those of the first snap structure 100a.

In this example, a right arm portion 103b of the first snap structure 100a and a left arm portion 103a of the second snap structure 100b, which is closer to the left arm portion 103b of the first snap structure 100a than a right arm portion of the second snap structure 100b, may be spaced apart from each other. That is, an outer arm side of the right arm portion 103b of the first snap structure 100a and an outer arm side of the left arm portion 103a of the second snap structure 100b may face each other. In addition, the outer arm sides of the right arm portion 103b of the first snap structure 100a and the left arm portion 103a of the second snap structure 100b may be formed with an electrically non-conductive material thereon.

In one embodiment, the electrical circuit board 10 may comprise a printed circuit board assembly (PCBA) comprising said electrical circuit 102 that can provide electrical connectivity between electrical components. In one embodiment, the board 10 may include a laminated sandwich structure of at least one electrically conductive layer and at least one insulating layer. The conductive layer may be etched to form a pattern of the trace 107 connecting between the circuit 102 and the plates 105a, 105b. The electrical circuit is shown by way of example, and other electrical circuits may also be implemented on the board 10.

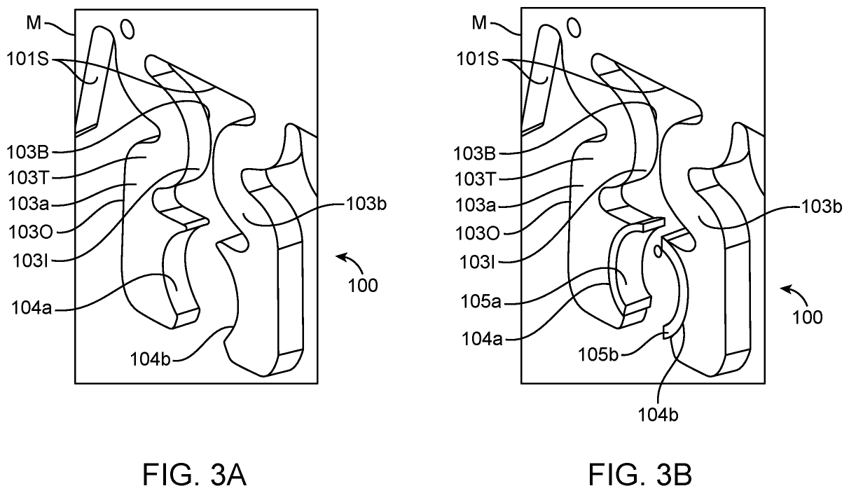

FIG. 3A depicts a magnified view of a portion M of the board in FIG. 2 and FIG. 3B depicts a magnified view of a portion M of FIG. 2 wherein a plate is formed on edge surfaces of the set of snap portions 104a, 104b, according to one embodiment. The body portion 101, the set of arm portions 103a, 103b, and the set of snap portions 104a, 104b may be one integrated form and may be manufactured by cutting an initial board to have contours including said body portion 101, the set of arm portions 103a, 103b, and the set of snap portions 104a, 104b. Thus, top surfaces of the body portion 101, the set of arm portions 103a, 103b, and the set of snap portions 104a, 104b may be at a same level and bottom surfaces thereof also may be at another level.

For example, the body portion 101 may have a first body surface 101T, a second body surface 101B opposite to the first body surface 101T, and a body side 101S between an edge of the first body surface 101T and an edge of the second body surface 101B. Further, each of the arm portions 103a, 103b may include a first arm surface 103T, a second arm surface 103B opposite to the first arm surface 103T, and an inner arm side 103I facing the other arm portion of the set of arm portions 103a, 103b, and an outer arm side 103O opposite to the inner arm side 103I. In this example implementation, the first arm surface 103T and the first body surface 101T may exist at a same level, and the second arm surface 103B and the second body surface 101B may exist at another level, such as different thickness levels as described further below.

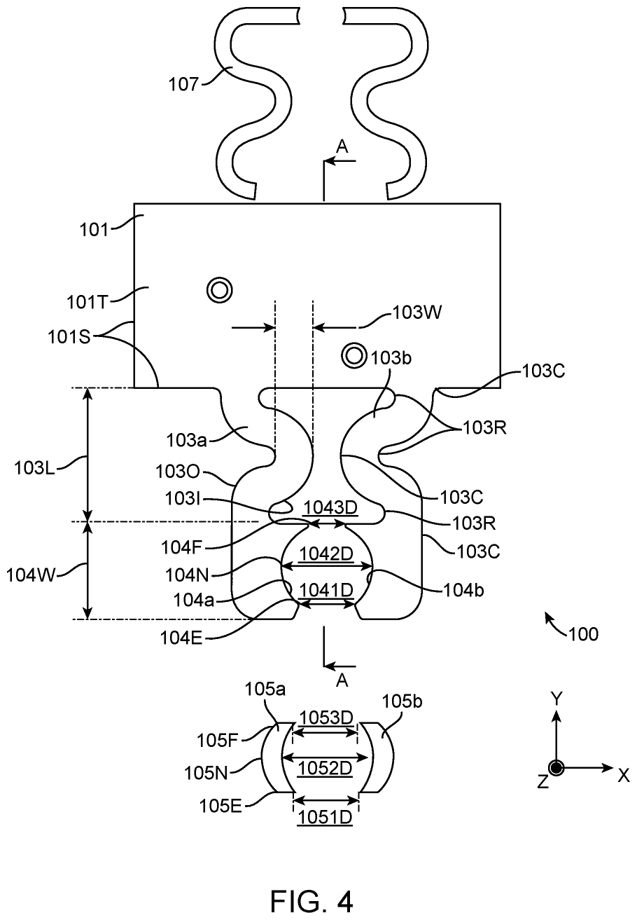

FIG. 4 depicts a top view of a disassembled portion M of the board 10 in FIG. 2, according to an embodiment disclosed herein. Referring to FIG. 4, each of the end surfaces of the snap portions 104a, 104b may include a proximal end point 104E, a distal end point 104F positioned away from the proximal end point 104E, and a medial end point 104N positioned between the proximal end point 104E and the distal end point 104F. In this example, a distance 1042D between the medial end points 104N of the snap portions 104a, 104b may be wider than a distance 1041D between the end points 104E of the snap portions 104a, 104b and a distance 1043D between the distal end points 104F of the snap portions 104a, 104b. In addition, a distance 1052D between medial end points 105N of the plates 105a, 105b corresponding to the medial end points 104N of the snap portions 104a, 104b may be wider than a distance 1051D between proximal end points 105E of the plates 105a, 105b corresponding to the proximal end points 104E of the snap portions 104a, 104b and a distance 1053D between distal end points 105F of the plates 105a, 105b corresponding to the distal end points 104F of the snap portions 104a, 104b.

In some embodiments, each of the end surfaces of the snap portions 104a, 104b and each of the plates 105a, 105b may have a concave shape. In other embodiments, a space defined by the end surfaces of the snap portions 104a, 104b and a space defined by the plates 105a, 105b on the snap portions 104a, 104b may have any one shape of: circle, ellipse, and oval. The end surfaces of the snap portions 104a, 104b and the plates 105a, 105b formed thereon are not limited to the shapes mentioned above and may be various shapes to snap on the electrical component effectively.

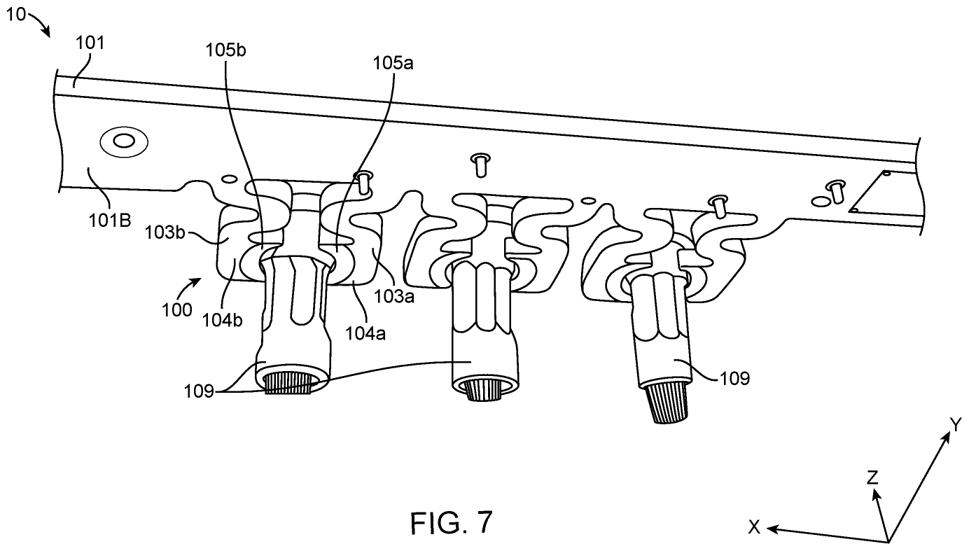

In some embodiments, to enhance stability of the connection between the snap portions 104a, 104b and an electrical component (such as shown in FIG. 7 described further below) while maintaining the flexibility of the arm portions 103a, 103b, a width 104W of each of the end surfaces of the snap portions 104a, 104b may be the wider than the width 103W of each of the arm portions 103a, 103b.

In some embodiments, the plates 105a, 105b may be formed on the end surfaces of the snap portions 104a, 104b, respectively. Each plate 105a, 105b may be formed across the proximal end point 104E, the medial end point 104N, and the distal end point 104F of the snap portion 104a, 104b. The plates 105a, 105b may directly contact with the other electrical components and serve as contact surfaces between the other electrical components and the trace 107 of the board 10. For this electrical connection, the plates 105a, 105b may be made of a conductive material. The plates 105a, 105b formed on the snap portions 104a, 104b may face and be spaced apart from each other, but are not limited thereto.

The trace 107 may be extended on top surfaces of the body portion 101, the set of arm portions 103a, 103b, and the set of snap portions 104a, 104b and connect between the circuit 102 and the set of plates 105a, 105b. The trace 107 disclosed herein may include any wiring component that is used to electrically connect between the plates 105a, 105b and an electrical component or the circuit 102 on the body portion 101. The trace 107 formed across the arm portions 103a, 103b may have a unique shape 102 according to the shape of the arm portions 103a, 103b. As mentioned above, each of the arm portions 103a, 103b may have a wave shape of having at least one of sine wave and square wave. In this case, the trace 107 also may have a wave shape according to the wave shape of the arm portions 103a, 103b.

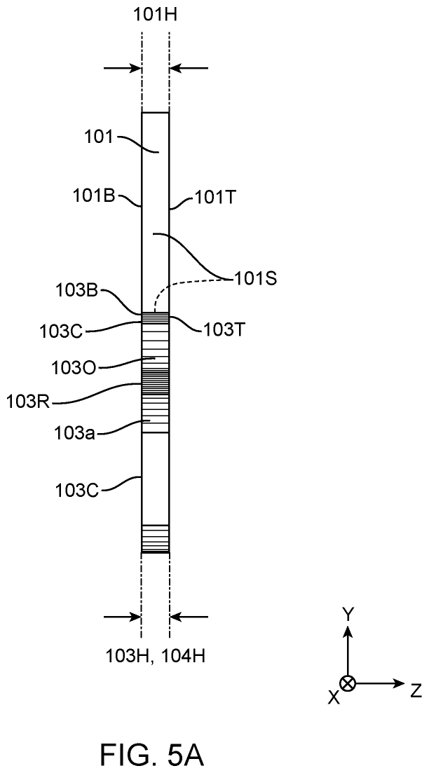

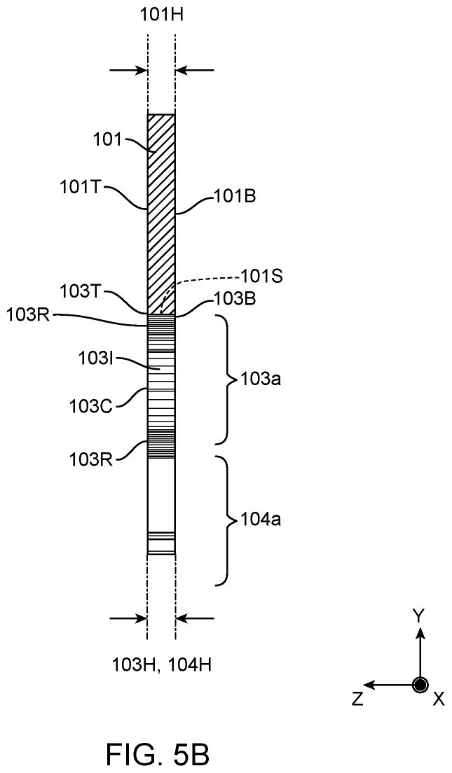

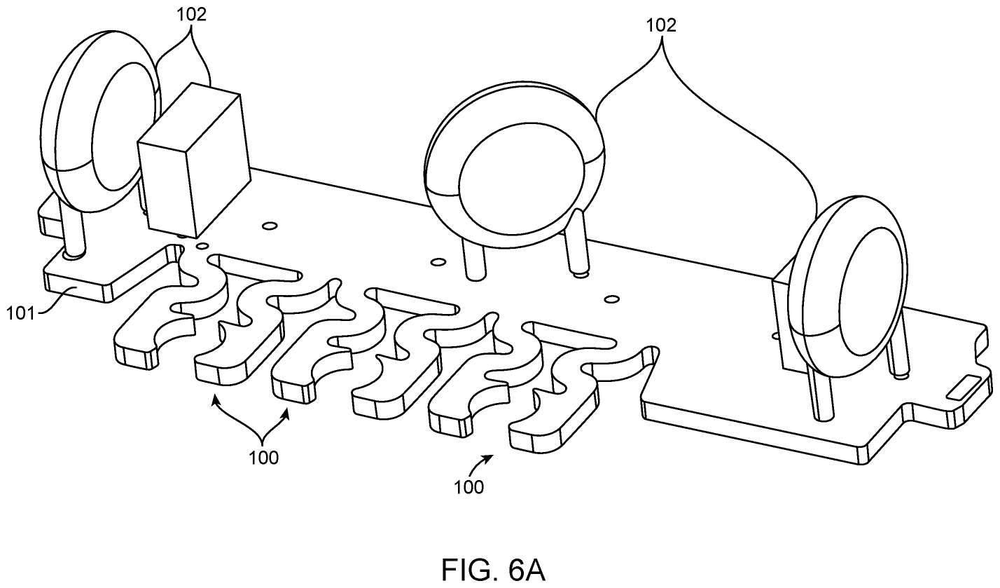

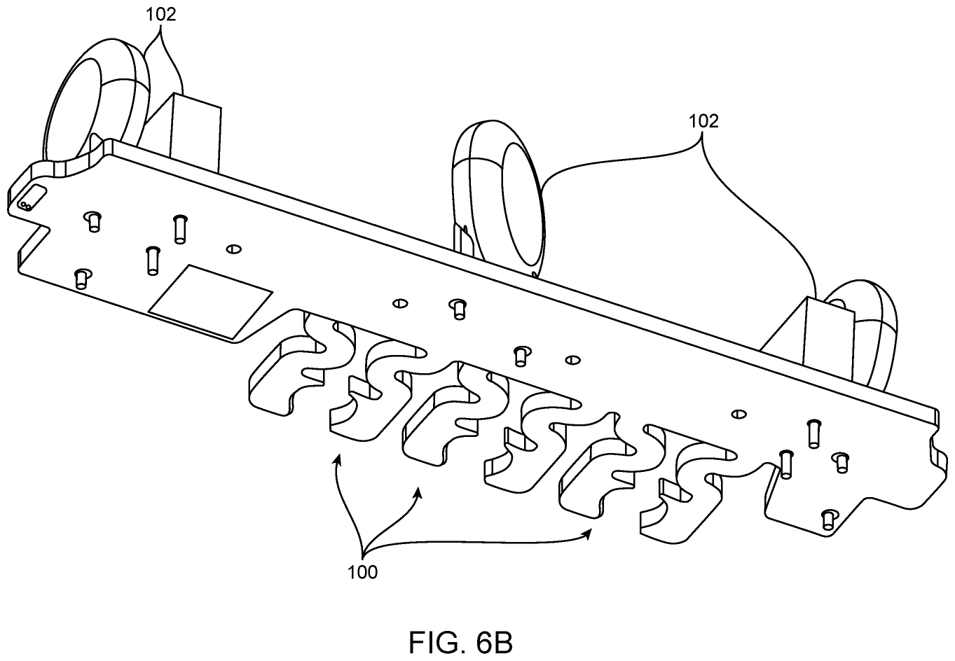

FIG. 5A depicts an outer side view of the board in FIG. 4, and FIG. 6B depicts an inner side view of the board, which is viewed from a line A-A in FIG. 4, according to an embodiment disclosed herein. Referring to side views in FIGS. 5 and 6, a thickness 101H of the body portion 101, a thickness of 103H each of the arm portion 103a, 103b, and a thickness 104H of each of the snap portions 104a, 104b may be the same as each other. In one embodiment, the body portion 101, the set of arm portions 103a, 103b, and the set of snap portions 104a, 104b may be one integrated body, and the integrated body may be a laminated sandwich structure including at least one insulating layer, each of the body portion 101, the set of arm portions 103a, 103b, and the set of snap portions 104a, 104b may share at least one insulating layer.

The set of arm portions 103a, 103b may outwardly extend from the body side 101S of the body portion 101. For example, the outer arm sides 103O and the inner arm sides 103I (shown in FIGS. 3A and 3B), may protrude from the body side 101S of the body portion 101 and be extended away from the body side 101S. Referring to top views in FIGS. 1 and 4 and bottom views in FIGS. 2 to 3B, each of the arm portions 103a, 103b may have a relatively narrow width 103W compared to its length 103L from the body side 101S to the end of each of the arm portions 103a, 103b. This configuration may allow the arm portions 103a, 103b to flexibly widen a space therebetween and then enable the edge surfaces of the snap portions 104a, 104b with the plates 105a, 105b to fittingly snap on an external electrical component therebetween, and frictionally/mechanically engage the external component (e.g., component 109 in FIG. 7, described further below).

Accordingly, the outer contour of the board 10 including the arm portions 103a, 103b, the board 10 itself may become a mechanical connector and may form a direct electrical connection between the external electrical component and the circuit 102 via the plates 105a, 105b and trace 107 without the need for a separate connector or additional electrical connection processes such as soldering.

In some embodiments, to improve flexibility of the arm portions 103a, 103b during the installation of the external electrical component, each of the arm portions 103a, 103b may include a wave shape of having at least one of sine wave and square wave. In this case, the wave shape of the arm portions 103a, 103b may include at least one crest and at least one trough. Specifically, referring to FIGS. 4, 5, and 6, each of the outer arm side 103O of the set of arm portions 103a, 103b may include two crests 103C and one trough 103R, and each of the inner arm sides 103I of the set of arm portions 103a, 103b may include one crest 103C and two troughs 103R.

The set of snap portions 104a, 104b may be formed on ends of the set of arm portions 103a, 103b, respectively, and the snap portions 104a, 104b may be positioned such that their edge surfaces face each other to hold or snap on an electrical component from its both sides via the plates 105a, 105b. In FIGS. 1-6, the edge surfaces of the snap portions 104a, 104b may be end surfaces of the snap portions 104a, 104b. The end surfaces of the snap portions 104a, 104b, which act as an interface, or a resting surface, to the external electrical component, may be edge-plated with an electrically conductive material. The plates 105a, 105b formed by edge plating may become direct contact surfaces to these electrical components and allow the electrical connection between the snapped electrical component and the trace 107.

FIG. 6A depicts a top perspective view of a board 10 without plates formed on edge surfaces of a set of snap portions 100, and FIG. 6B depicts a bottom perspective view of the board 10 shown in FIG. 6A.

Referring to FIGS. 6A and 6B, the board 10 may have an electrical circuit or a conductive component 102 that is disposed thereon. The electrical circuit or conductive component 102 may include various types of PCB components such as capacitors, resistors, inductors, diodes, microchips, transistors, etc.

FIG. 7 depicts a bottom perspective view of a board 10 according to an embodiment disclosed herein, wherein the board 10 snaps on to external electrical component and forms a direct electrical connection thereto. Each snap structure 100 of the board 10, such as snap structure 100a, provides a snap-fit mechanism including flexible arms 103a, 103b, for interlocking with elements of an external electrical component 108, allowing an assembly method for attaching flexible parts by pressing the snap structure 100a onto a part of the external component 109, wherein the arms 103a and 103b flex to open, engage, and maintain the external component 109. Referring to FIG. 7 along with FIG. 1, the board 10 may snap on and be electrically connected to the external electrical components 109, via three snap structures 100. The edge surfaces of the snap portions 104a, 104b, which act as an interface to the electrical component 109, may be edge-plated with an electrically conductive material to form the plates 105a, 105b. The mechanical and/or electromechanical connection between the board 10 and the electrical component 109 may be formed via a snap-hook mechanism of the snap portions 104a, 104b. This design may allow the board 10 to snap directly onto other electrical components, thereby eliminating the need for separate connectors and additional electrical connection processes.

The plates 105a, 105b formed on the edge surfaces of the snap portions 104a, 104b may be directly in contact with the electrical components 109 snapped on therebetween and form an electrical connection between the electrical component EC and the circuit 102, via the trace 107 connected to the plates 105a, 105b. The electrical component 109 snapped on may be various elements including electrically conducting components/parts.

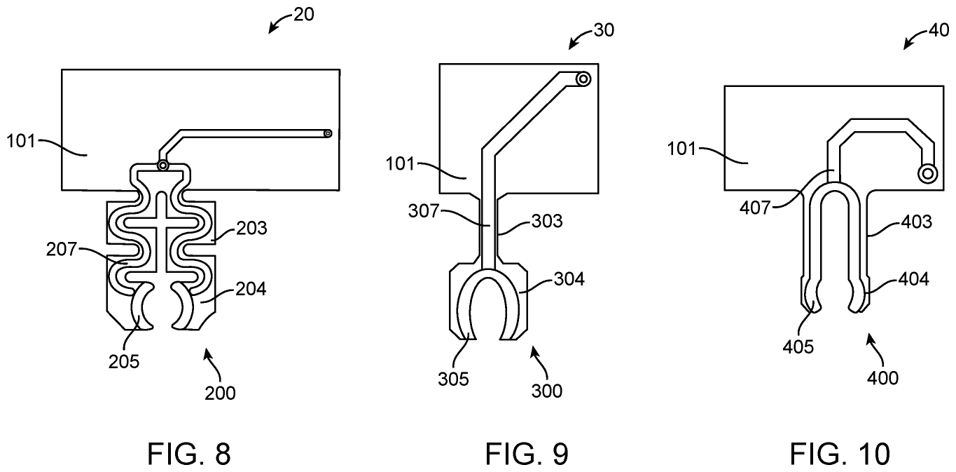

FIG. 8 depicts a top view of a board comprising a set of arm portions with a square wave shape, according to an embodiment of the disclosure. Referring to FIG. 8, a board 20 may comprise a set of arm portions 203 each having a square wave. The square wave of each of the arm portion 203 may have two crests and two troughs, but the numbers of crest and trough are not limited thereto. As mentioned above, a length of each of the arm portions 203 may be longer than a width of each of the arm portions 203 to improve flexibility of the arm portions 203 during installation of an electrical component.

Snap portions 204 may be formed on ends of the arm portions 203, respectively, such that edge surfaces of the snap portions 204 may face each other to snap on the electrical component therebetween. In some embodiments, a width of each of the snap portions 204 may be wider than the width of each of the arm portions 203. Plates 205 made of a conducting material may be formed on the edge surfaces of the snap portions 204.

On top surfaces of the body portion 101, the arm portions 203, and the snap portion 204, a trace 207 may be formed connecting between the plates 205 and a circuit on the body portion 101. A shape of the trace 207 also may have a wave shape corresponding to the square wave shape of the arm portions 203. In this case, the wave shape of the trace 207 may have a sine wave shape corresponding to the square wave shape of the arm portions 203 but is not limited thereto.

FIG. 9 depicts a top view of a board comprising a single arm portion, according to an embodiment of the disclosure. Referring to FIG. 9, a board 30 may comprise a single arm portion 303 instead of a set of arm portions 103a, 103b, 203 as shown in FIGS. 1 and 8. For example, the board 30 may comprise a single arm portion 303 extended from the body side of the body portion 101 and two separated snap portions 304 branched off from an end of the single arm portion 303. The snap portions 304 may be extended away from the end of the single arm portion 303, having a varying distance therebetween. In this case, the edge surfaces of the snap portions 304, which serve as an interface to an electrical component, may be inner side surfaces of the snap portions 304. A distance between the end points of the snap portions 304 and a distance between the distal end points of the snap portions 304 may be narrower than a distance between the medial end points of the snap portions 304, where the medial end point is a point positioned between the end point and the distal end point in the inner side surface of each of the snap portion 304. In some embodiments, an inner side surface of each of the snap portions 304 may have any one shape of concave, circle, ellipse, and oval. The shape of the snap portion 304 is not limited thereto and may be modified to snap an electrical component effectively.

A plate 305 may be formed over the inner side surfaces of the snap portions 304. The plate 305 may be continuously extended on each of the inner side surfaces of the snap portions 304 and connect with each other at a center of the snap portions 304. In this case, the snap portions 304 may have a shape of horseshoe. An electrically conductive trace 307 may be formed across the top surfaces (or inside) of the body portion 101, the single arm portion 303, and the snap portions 304 and connected to a center of the plate 305.

FIG. 10 depicts a top view of a board comprising a single plate for a set of arm portions and a set of snap portions, according to an embodiment of the disclosure. Referring to FIG. 10, a board 40 may comprise a set of arm portions 403, a set of snap portions 404, and a single plate 405. Specifically, the arm portions 403 may be extended from a body side of the body portion 101 with certain distances therebetween, and inner arm sides of the arm portions 403 may face each other. The arm portions 403 may have a linear shape but is not limited thereto.

The snap portions 404 may be formed on the ends of the arm portions 403 and extended in a parallel direction to that of the arm portions 403. In this case, the edge surfaces of the snap portions 404, which serve as an interface to an electrical component, may be inner side surfaces of the snap portions 404, and the inner side surfaces of the snap portions 404 may be formed to face each other. In some embodiments, the distance between the end points of the snap portions 404 and the distance between the distal end points of the snap portions 404 may be narrower than the distance between the medial end points of the snap portions 404. In other embodiments, the inner side surfaces of the snap portions 404 may have any one shape of concave, circle, ellipse, and oval. The shape of the snap portion 404 is not limited thereto and may be modified to snap an electrical component effectively.

The plate 405 may be extended from the inner side surface of the snap portions 404 to the inner arm sides of the arm portions 403. Furthermore, the plate 405 may be further formed on the body side of the body portion 101 disposed between the arm portions 403. In this example, a portion of the plate 405 formed on each of the inner arm sides of the arm portions 403 may be connected to each other through a portion of plate 405 formed on the body side of the body portion 101. Accordingly, the plate 405 may be a single plate extended from the inner side surface of one snap portion 404 to the inner side surface of the other snap portion 404 through the inner arm sides of the arm portions 403 and the body side. Thus, the snap portions 404 may have a shape of long horseshoe. An electrically conductive trace 407 may be formed across the top surfaces of the body portion 101 and connected to the center of the plate 405 formed on the body side of the body portion 101.

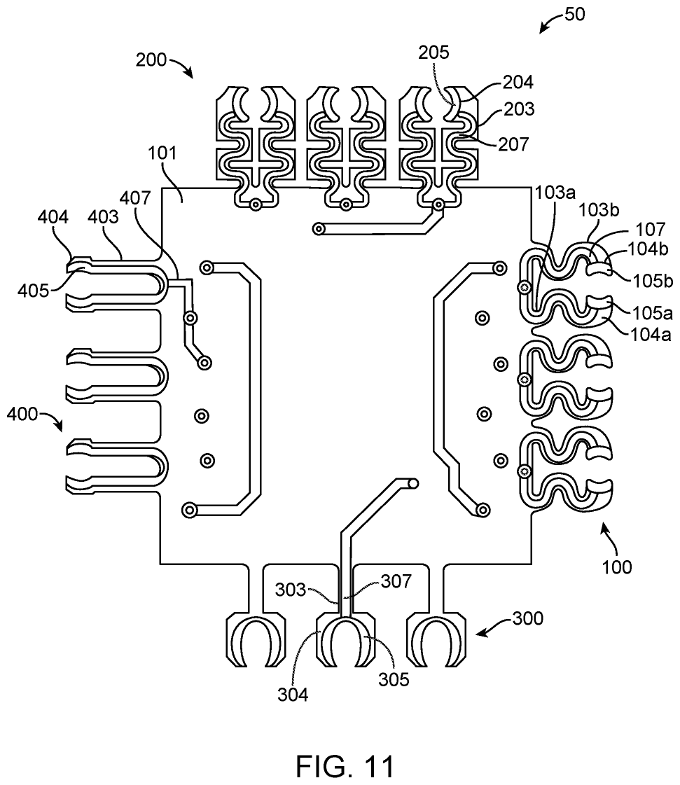

FIG. 11 depicts a board with a plurality of snap structures having different shapes, according to an embodiment of the disclosure. Referring to FIG. 11, a board 50 may comprise a plurality of snap structures extended from a body side of a single body portion 101. The plurality of snap structures may include a first snap structure 100 shown in FIGS. 1 to 6, a second snap structure 200 shown in FIG. 8, a third snap structure 300 shown in FIG. 9, and a fourth snap structure 400 shown in FIG. 10. The shapes and/or number of the snap structures may be selected based on the need for connecting electrical components. Though the body portion 101 is shown as essentially a planar and rectangular shape in the embodiment disclose herein, embodiments are not disclosed to the example herein. For example, the body portion 101 can have other geometric shapes such as circular, elongated, curved, etc. Further, in other examples the body portion 101 may comprise three-dimensional shape.

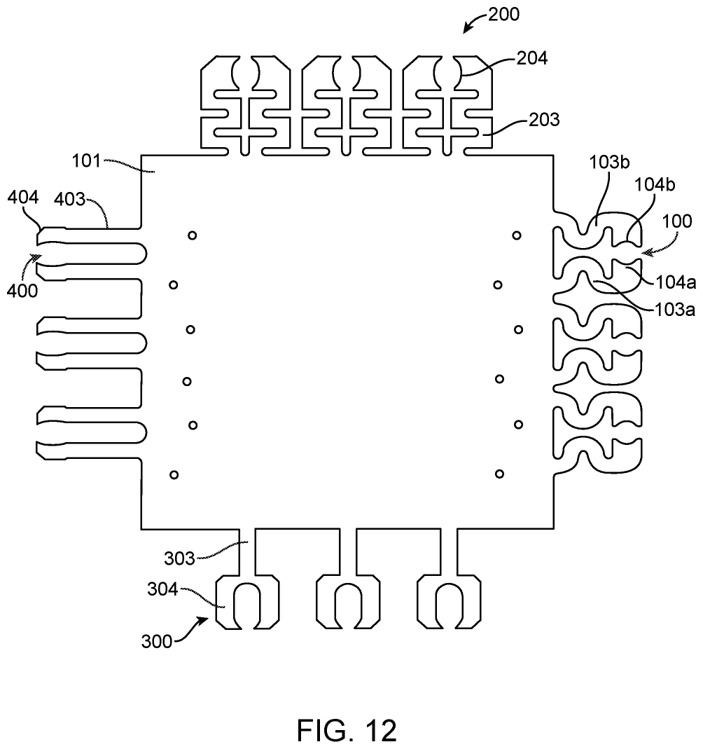

FIG. 12 depicts a top view of a board 50 shown in FIG. 11 in a state where plates are not formed on edge surfaces of sets of snap portions 104a, 104b, 204, 304, 404, according to an embodiment of the disclosure.

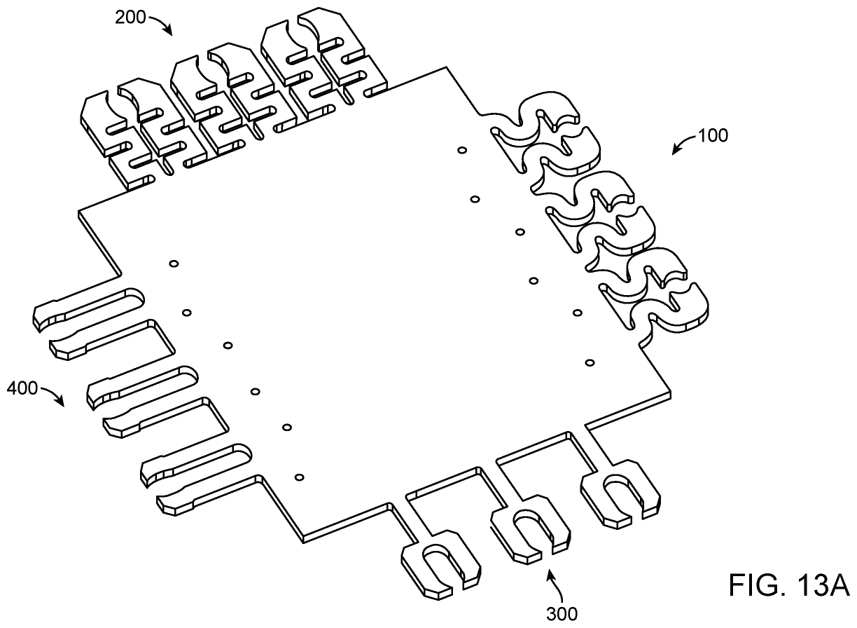

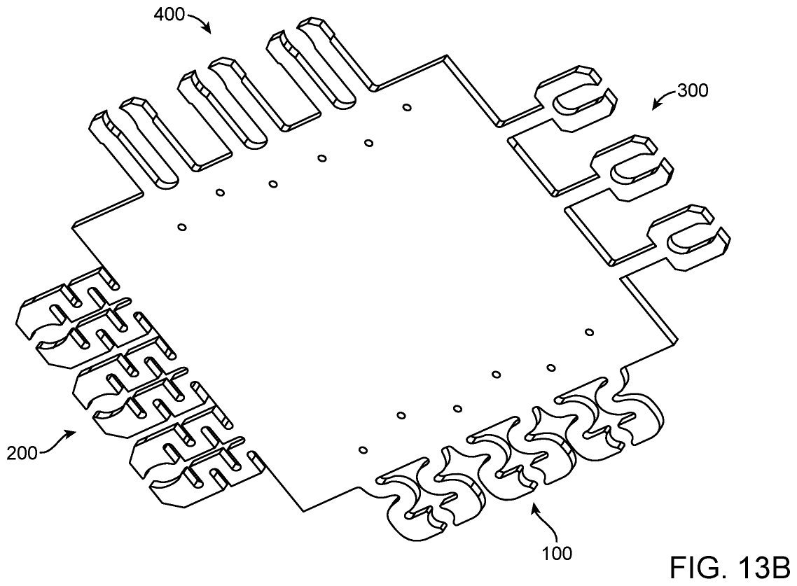

FIG. 13A depicts a top perspective view of a board 50 in FIG. 11 in a state where plates are not formed on edge surfaces of sets of snap portions 104a, 104b, 204, 304, 404, according to an embodiment of the disclosure.

FIG. 13B depicts a bottom perspective view of a board 50 in FIG. 11 in a state where plates are not formed on edge surfaces of sets of snap portions 104a, 104b, 204, 304, 404, according to an embodiment of the disclosure.

As described above, according to the present disclosure, the mechanical connection to an outer electrical component can be created via a snap-hook mechanism of the snap structure of the board. This design allows the board to be snapped directly onto other electrical components, thereby eliminating the need for additional connectors and/or additional connection processes, which are conventionally required for electrical connection between a board and other electrical components. Accordingly, the board of the present disclosure can save cost for additional components that are conventionally required for electrical connection and reduce a production time of a board by eliminating an installation time of those additional components in a board.

It is contemplated that various combinations and/or sub-combinations of the specific features and aspects of the above embodiments may be made and still fall within the scope of the invention. Accordingly, it should be understood that various features and aspects of the disclosed embodiments may be combined with or substituted for one another in order to form varying modes of the disclosed invention. Further, it is intended that the scope of the present invention is herein disclosed by way of examples and should not be limited by the particular disclosed embodiments described above.

What is claimed is:

1. A board assembly comprising:
a body portion configured to maintain an electrical circuit thereon; and
at least one engagement mechanism at a periphery of the body portion, wherein the engagement mechanism is configured to mechanically engage an external component, and provide electrical connection between the electrical circuit and the external component.

2. The board assembly of claim 1, wherein the engagement mechanism comprises a snap structure.

3. The board assembly of claim 2, wherein each snap structure comprises:
a set of arm portions extending from a side of the body portion; and
a set of snap portions, the snap portions formed on ends of the arm portions.

4. The board assembly of claim 3, wherein each snap structure further comprises:
a set of electrically conductive edge-plates, the edge-plates formed on edge surfaces of the snap portions.

5. The board assembly of claim 4, further comprising:
an electrically conductive trace extending across top surfaces of the body portion, the set of arm portions, and the set of snap portions, wherein the trace is connected between the electrical circuit to at least one of the set of edge-plates.

6. The board assembly of claim 3, wherein the body portion, the set of arm portions, and the set of snap portions from an integrated body.

7. The board assembly of claim 6, wherein:
the integrated body has a laminated sandwich structure including at least one insulating layer, and the body portion; and
the set of arm portions, and the set of snap portions share the at least one insulating layer.

8. The board assembly of claim 3, wherein each of the arm portions includes a first arm surface, a second arm surface opposite to the first arm surface, an inner arm side facing the other arm portion of the set of arm portions and an outer arm side opposite to the inner arm side.

9. The board assembly of claim 8, wherein:
the body portion has a first body surface, a second body surface opposite to the first body surface, and a body side between an edge of the first body surface and an edge of the second body surface;
the outer arm sides protrude from the body side; and
the inner arm sides protrude from the body side.

10. The board assembly of claim 5, wherein:
each of the edge surfaces of the snap portions includes: a proximal end point, a distal end point positioned away from the proximal end point, and a medial end point positioned between the proximal end point and the far end point; and
a distance between the medial end points is wider than a distance between the proximal end points and a distance between the distal end points.

11. The board assembly of claim 10, wherein a distance between the medial end points of the plates corresponding to the medial end points of the snap portions is wider than a distance between end proximal points of the plates corresponding to the proximal end points of the snap portions and a distance between distal end points of the edge-plates corresponding to the distal end points of the snap portions.

12. The board assembly of claim 5, wherein:
each of the edge surfaces of the snap portions and each of the edge-plates on each of the end surfaces of the snap portions, comprises at least one of: concave, circle, ellipse and oval shape;
each of the arm portions includes a wave shape having at least one of: a sine wave and a square wave; and
the trace formed on the arm portions has a wave shape according to the wave shape of the arm portions.

13. The board assembly of claim 8, wherein outer arm sides of the arm portions are formed with an electrically non-conductive material thereon.

14. A printed circuit board assembly, comprising:
a printed circuit board having a body portion to maintain an electrical circuit thereon;
at least one snap-fit mechanism, each snap-fit mechanism comprising:
at least one arm portion formed on a side of the body portion;
a set of snap portions formed on at least one end of the at least one arm portion;
at least one edge-plate formed on edge surfaces of the snap portions; and
an electrically conductive trace connected between the electrical circuit and the at least one edge-plate.

15. The printed circuit board assembly of claim 14, wherein:
the at least one arm portion comprises a single arm portion, and the snap portions branch off from an end of the single arm portion, and
wherein the at least one edge-plate comprises a single edge-plate that continuously extends from at least one of the edge surfaces of the snap portions to the other of the edge surfaces of the snap portions.

16. The printed circuit board assembly of claim 14, wherein:
the at least one arm portion comprises a set of arm portions, and the snap portions are formed on ends of the arm portions, and
the at least one edge-plate comprises a single plate continuously formed on the edge surfaces of: the snap portions, inner arm sides of the arm portions, and the body side of the body portion disposed between the arm portions.

17. The printed circuit board of claim 14, comprising a plurality of spaced snap structures.

18. The printed circuit board of claim 15, comprising a plurality of snap structures having at least two different shapes.

19. A method of connecting electrical components, comprising:
providing a board assembly comprising a body portion configured to maintain an electrical circuit thereon, and at least one snap-fit engagement mechanism at a periphery of the body portion, wherein the engagement mechanism is configured to mechanically engage an external component, and provide electrical connection between the electrical circuit and the external component; and
connecting the board assembly to an electrical component by pressing the snap-fit engagement mechanism against the electrical component to engage, and electrically connect to, the electrical component via the snap-fit engagement mechanism.

20. The method of claim 19, wherein the snap-fit engagement mechanism is electrically conductive.
